(19) United States
(12) Patent Application Publication
(10) Pub. No.: US 2007/0072338 A1
(43) Pub. Date: Mar. 29, 2007

(54) Method for separating package of WLP

(75) Inventors: Wen-Kun Yang, Hsin-Chu City (TW); Chun Hui Yu, Tainan City (TW); Jui-Hsien Chang, Jhudong Township (TW); Hsien-Wen Hsu, Lujhou City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/235,484

(22) Filed: Sep. 26, 2005

(51) Int. Cl. H01L 21/00; H01L 23/02

(52) U.S. Cl. 438/106; 257/678; 257/E21.237

(57) ABSTRACT

The present invention provides a semiconductor device package singulation method. The method comprises printing a photo epoxy layer on the back surface of a substrate of a wafer for marking the scribe lines to be diced. Then etching is performed through the substrate along the marks in the photo epoxy layer. Dicing the panel into individual package with a typical art designing knife, the step not only avoids the roughness on the edge of each die, but also decrease the cost of singulation process.

### BACKGROUND OF THE INVENTION

1. Field of the Invention

This invention relates generally to semiconductor device packaging, and more particularly to a dicing method of semiconductor devices package for dividing the panel into discrete package.

2. Description of the Prior Art

In the electronic component world, integrated circuits (IC's) are typically fabricated on a semiconductor substrate, known as a chip, and most commonly are made of silicon. The silicon chip is typically assembled into a larger package, which serves to provide effective enlargement of the distance or pitch between input/output contacts of the silicon making it suitable for attachment to a printed circuit board, and to protect the IC from mechanical and environmental damage.

Conventionally, ICs are packaged one by one after dicing from a wafer. A wafer level package (WLP) or a chip scale package (CSP) was developed to provide an alternative solution to directly attached flip chips devices, and plurality of dice are separated into individual devices after they are packaged. Die separation, or dicing, by sawing is the process of cutting a semiconductor substrate into its individual die. Wafer dicing technology has progressed rapidly to satisfy every packaging requirement, such as high throughput, high yield and low cost.

As shown in FIG. 1, it is a side view of plurality of flip chip devices 100 in a wafer according to prior art. The flip chip 100 includes a die 105 with metal pads 106 that typically has a conventionally fabricated IC device structure. The die 105 is adhered on a substrate 102 through an adhesive layer 104, and the die 105 has a plurality of electrical connections 108, such as redistribution layer (RDL) trace. Bumps, such as solder balls 107, are formed on the electrical connections 108. A protection layer 109 covers the electrical connections 108 to expose a portion of the electrical connections 108 for allowing the solder balls 107 formed thereon. Moreover, a buffer film 101 is applied to the bottom surface of the substrate 102.

Devices 100 are generally separated from each other and the rest of the panel by a saw blade cutting along the dash line 110 from the surface having the solder balls 107. The dicing blade is usually made of some hard materials, there are some kinds of blades available commercially: (1) sintered diamond blade, in which diamond particles are fused into a soft metal such as brass or copper, or incorporated by means of a powdered metallurgical process; (2) plated diamond blade, in which diamond particles are held in a nickel bond produced by an electroplating process; (3) resinoid diamond blade, in which diamond particles are held in a resin to create a homogeneous matrix. Silicon wafer dicing is dominated by the plated diamond blade, which has proved most successful for this application.

While saw cutting of wafers and panel is the conventional industry standard, there remain drawbacks with such cutting. Saw blade wear over time. This results in inconsistent cutting quality from when the blade is new and subsequent cutting operations. Consequently, the operator must predict when the blade has reached the end of its useful lifetime. This cannot be predicted accurately. Accordingly, the saw blades may be changed before the end of their useful lives resulting in higher equipment costs than necessary due to premature saw blade replacement. Moreover, saw blades introduce mechanical stresses in the workpiece while sawing, especially at the surfaces of the workpiece. Due to these stresses saw blade may not be used to cut very thin workpieces, such as ultrathin semiconductor wafers. Increasing use of integrated circuits (IC's) technology in microwave and hybrid circuits, memories, computers, defense and medical electronics has created new difficult problems for the industry.

The other drawback of using saw is time consuming. It usually takes 2 to 3 hours to process a wafer. It affects not only the throughput of products, but it is a cost of processing a wafer and panel.

Another drawback of dicing wafer with a saw blade is the costs. Because the blades are no ordinary blades, they are more expensive than general knifes. It costs about US$60 dollars for one dicing blade, and each dicing machine has more than one blade depending on the design.

There is still a drawback of dicing wafers with a saw blade. The edges cut by a dicing saw of each die are rough. Because the cutting process is an abrasive machining process similar to grinding and cutoff operations, the edges of each die are usually very rough and easy chipping.

In view of the aforementioned, the present invention provides an improved method of separating package for WLP to overcome the above drawback.

### SUMMARY OF THE INVENTION

To achieve the foregoing and other objects and according to the purpose of the present invention, a semiconductor device package dicing method for fabricating the same are disclosed.

The dicing method of semiconductor device package of the present invention can avoid the roughness on the edge of each package after dicing with a dicing saw.

The dicing method of the present invention may avoid the high cost because of using a dicing saw, and also avoid the time consuming matter of dicing a panel.

The present invention provides a method for separating package of wafer level package. The method comprises: (a) printing a buffer layer on the first surface of a substrate, wherein the buffer layer has grooves denoting each die; (b) cutting the package from the second surface of the wafer level package along a cutting line with mechanical force such as a knife; and (c) etching through the substrate of the wafer level package device along the grooves.

Wherein the material of the buffer layer includes photo epoxy. Wherein the depth of the grooves are substantially equal to the thickness of the buffer layer. Wherein the width of the grooves are substantial fixing. Wherein the etching step includes wet etching process, and the etching solution includes: ferric chloride, cupric chloride, and ammonium persulfate. Wherein the material of the substrate layer in the etching step comprises silicon, glass, alloy 42, quartz or ceramic. Wherein the knife in the etching step includes: an art-designing knife.

In another aspect, the present invention discloses a semiconductor device package structure. The structure comprises a die having a plurality of electrical contacts on a first surface of the die. A plurality of conductive balls is coupled to the contacts. A substrate is adhered on a second surface of the die. A first buffer layer is formed on the substrate and adjacent to the die. A second buffer layer is configured over the substrate, wherein the substrate and the second buffer layer have recesses to the first buffer layer. Wherein the recesses in the protective layer are approximate the half widths of the grooves.

The buffer layer may reach the function to avoid the dice or substrate from damaging when the side part of the dice or substrate collides with an external object.

### BRIEF DESCRIPTION OF THE DRAWINGS

The above objects, and other features and advantages of the present invention will become more apparent after reading the following detailed description when taken in conjunction with the drawings, in which:

FIG. 1 is a diagrammatic side view of a fan-out wafer (panel) level package according to the prior art.

FIG. 2A is a schematic diagram of a semiconductor wafer according to the present invention.

FIG. 2B is a schematic diagram of a semiconductor wafer according to the present invention.

FIG. 2C is a schematic diagram of a semiconductor wafer according to the present invention.

FIG. 2D is a schematic diagram of a semiconductor wafer according to one embodiment of the present invention.

FIG. 2E is a schematic diagram of a semiconductor wafer according to one embodiment of the present invention.

FIG. 2F is a schematic diagram of a semiconductor wafer according to one embodiment of the present invention

FIG. 3A is a schematic diagram of an individual semiconductor device package structure according to the present invention.

FIG. 3B is a schematic diagram of an individual semiconductor device package structure according to the present invention.

FIG. 3C is a schematic diagram of an individual semiconductor device package structure according to the present invention.

FIG. 3D is a schematic diagram of an individual semiconductor device package structure according to the present invention.

### DESCRIPTION OF THE PREFERRED EMBODIMENT

Method and structure for manufacturing a semiconductor device (such as integrated circuit) or a substrate is described below. In the following description, numerous specific details are set forth in order to provide a thorough understanding of the present invention, and the scope of the present invention is expressly not limited expect as specified in the accompanying claims.

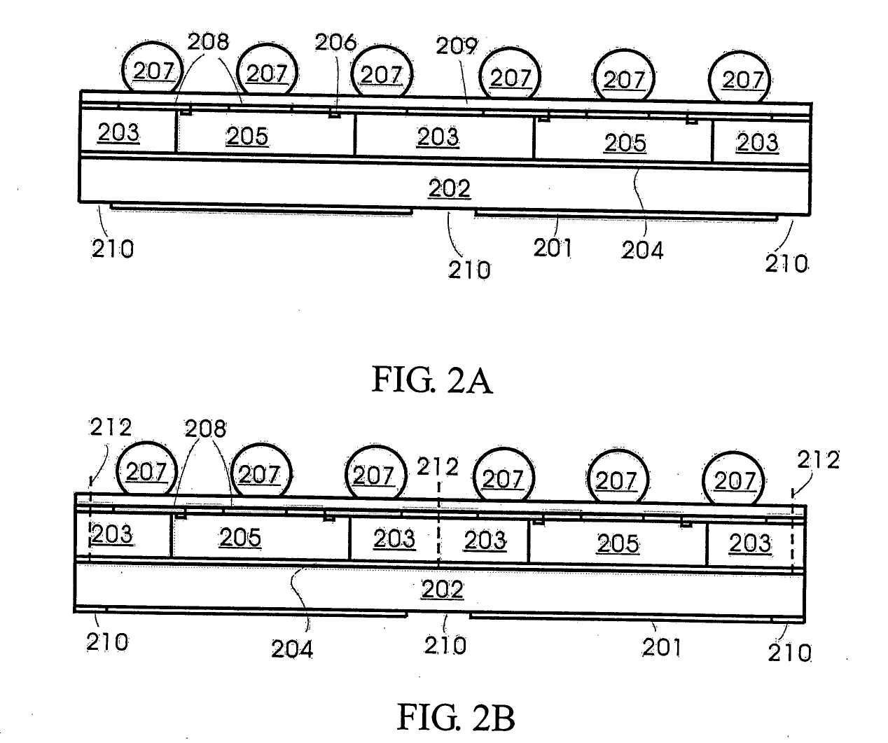

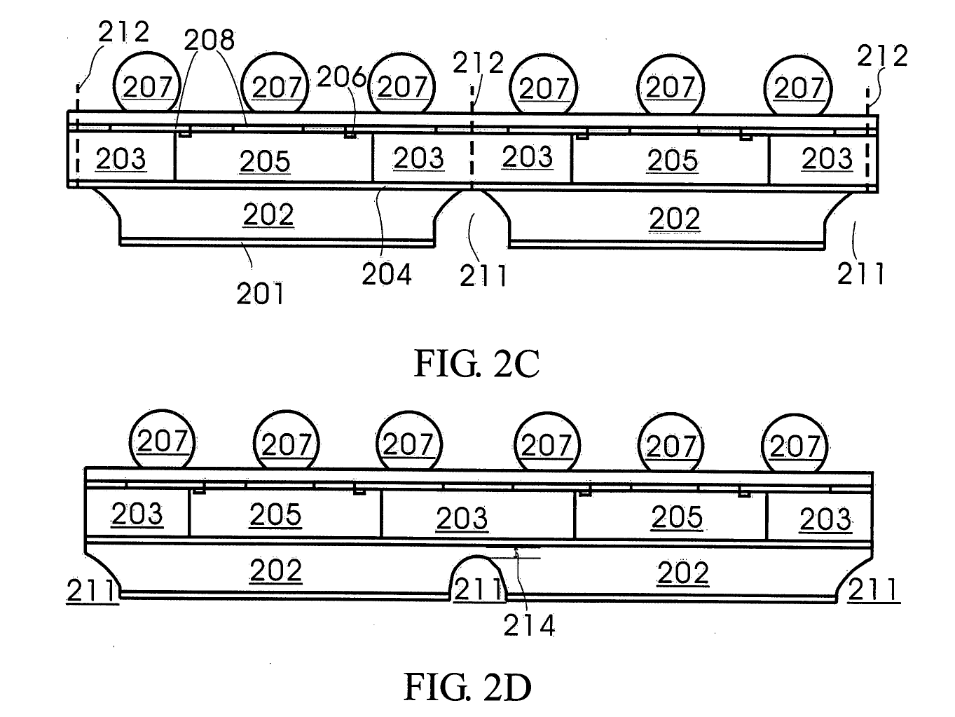

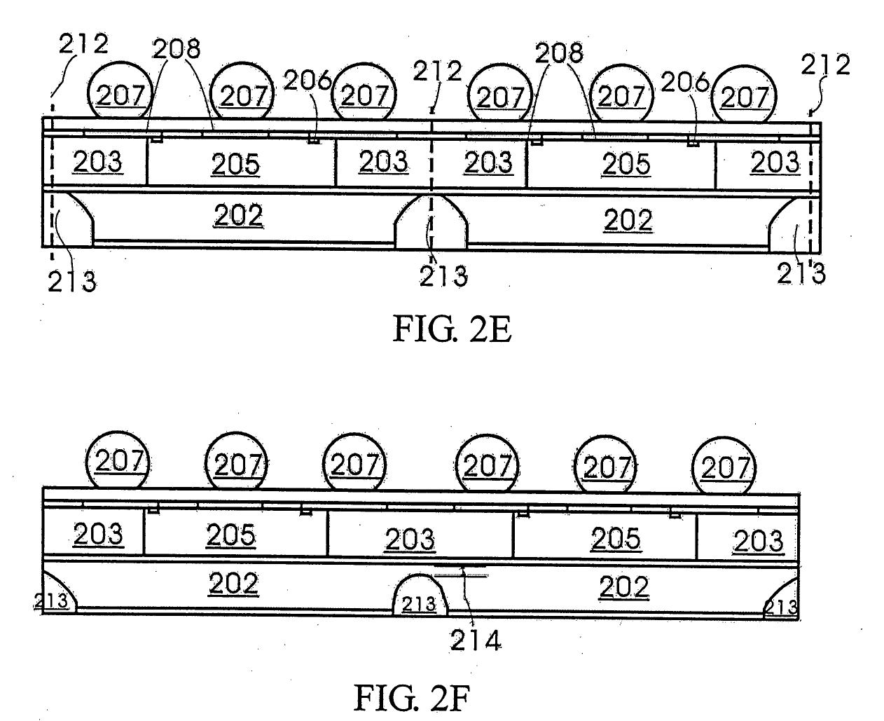

Referring to FIG. 2A, a portion of wafer 200 comprises plurality of chip 205 with metal pads 206 and contact metal balls 207 formed thereon electrically coupling with a print circuit board (not shown). A protection layer 209 covers the electrical connections 208 to expose a portion of the electrical connections 208 for allowing the contact metal balls 207 formed thereon.

A backside surface of the chip 205 is directly adhered on a substrate 202 through an adhesive layer 204, and a first buffer layer 203 is formed on the substrate 202 and adjacent to the chip 205. It should be note that the dimension of the substrate 202 is larger than the one of the chip 205. The electrical connections 208 are metal alloy, for example Ti/Cu alloy formed by sputtering and/or Cu/Ni/Au alloy formed by electroplating. The material of the first buffer layer 203 comprises core material, which is an elastic material, such as silicone rubber, silicone resin, elastic PU, porous PU, acrylic rubber, blue tape or UV tape. The substrate 202 comprises but not limited to silicon, glass, alloy 42, quartz or ceramic.

In one embodiment, the first step of the dicing method according to the patent is to print a second buffer layer 201 on the backside of substrate 202. There are grooves 210 that are located between each chip 205 within the second buffer layer 201 and substantially aligned to the first buffer layer 203. The distance between each groove 210 is substantially fixed, and depends on the size of each device package after dicing. The depth of each groove 210 is substantially equal to the thickness of the second buffer layer 201. The material of the second buffer layer 201 comprises photo epoxy.

Referring to FIG. 2B, the second step of the dicing method according to the patent is: cutting the wafer 200 along cutting lines 212 in buffer layer 203. The cutting lines 212 are approximately in the center of the grooves 210. The dicing step can be performed from the side having solder balls. The material of buffer layer 203 includes: silicon rubber, which can be easily cut through by any kind of knifes, such as an art designing knife.

After the dicing step performed above, the third step of dicing wafer according to the patent is etching through the substrate 202 along the grooves 210. And the second buffer layer 201 has grooves within it, which indicate the scribe lines of each die. The buffer layer 201 may reach the function to reduce the die from being lateral damage due to less contact area of the die when the side part of the dice collides with a lateral external object.

As shown in FIG. 2C, the substrate 202 is etched by wet etching process along the grooves 210 within the second buffer layer 201. The etching solution comprises: ferric chloride, cupric chloride, and ammonium persulfate. And the substrate 202 is divided into separated portions by the etching routes 211. The etching routes 211 starts from the grooves 210 within the second buffer layer 201 to the first buffer layer 203.

There can be a small portion of substrate 202 left between the etching routes 211 and the first buffer layer 203, as shown in FIG. 2D. In one embodiment, the thickness of the residue 214 between the etching routes 211 and the first buffer layer 203 is less than 50 um.

The second step and the third step can be switched, that is etching the substrate layer and then cutting the wafer 200 into plurality of separated packages. In one embodiment, the etching routes 211 are filled with core material, which is an elastic material, such as silicone rubber, silicone resin, elastic PU, porous PU, acrylic rubber, blue tape or UV tape, as shown in FIG. 2E. The cutting can be performed from either side of the wafer 200.

There is still another embodiment according to the patent, as shown in FIG. 2F. The etching step is performed prior to the cutting step. The residue 214 of the substrate 202 is less than 50 um, and core materials 213 is filled in the etching route 211. Then the cutting is performed from either side of the wafer 200.

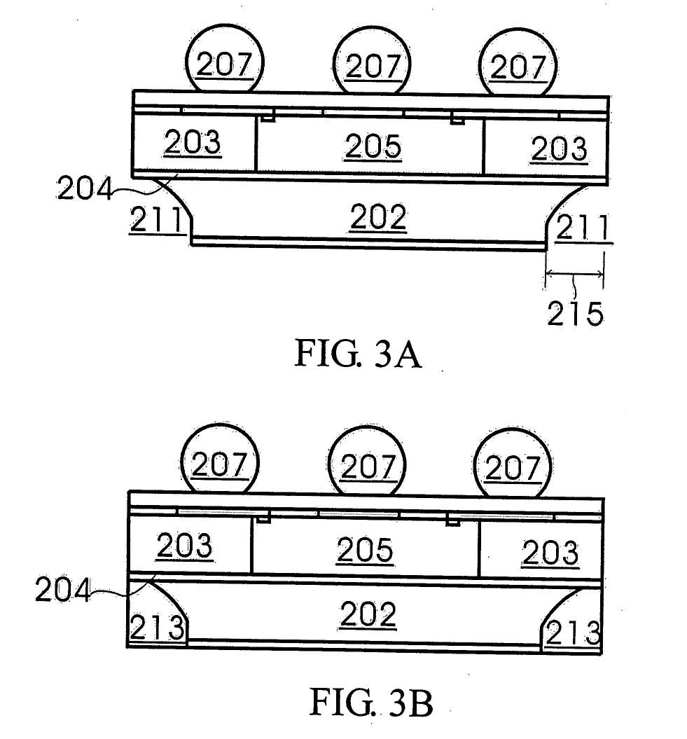

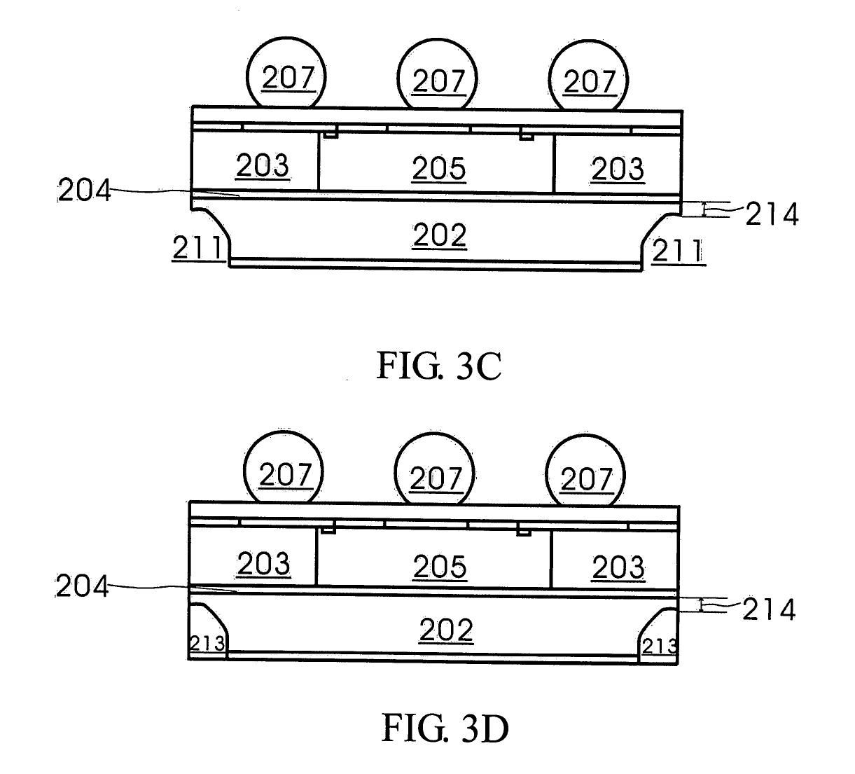

After dicing process of the patent, the panel is separated into individual package, and there are four kinds of package structures according to the patent, which are shown in FIGS. 3A, 3B, 3C and 3D respectively. In FIG. 3A, the substrate 202 is etched throughout and forming an recess 215 along the edge of the substrate 202 and the second buffer layer 201. In FIG. 3B, core material 213 is filled in the recess 215. In FIG. 3C, the substrate 202 is not etched throughout, therefore residue 214 is left along the edge of the package. In FIG. 3D, package with residue 214 of substrate 202 and the recess 215 is filled with core material 213 along the edge.

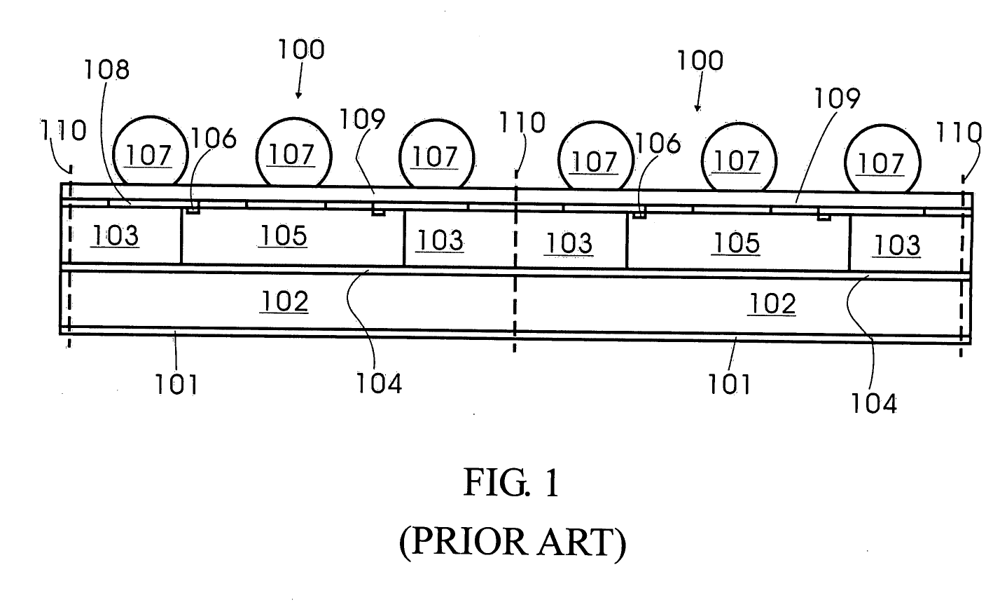

In another aspect, the present invention discloses a semiconductor device package structure wherein the edge of substrate layer 202 and the second buffer layer 201 may have recess to buffer layer 203. The structure of die 213 is different from general dies dicing by well-known technology as shown in FIG. 1. The width of each layers of the die 111 cut by general dicing saw is substantial equal. And the edge of dies 111 may be rough due to the general effect of sawing.

Hence, according to the present invention, the aforementioned semiconductor device package structure dicing by the method according to the patent is different with general device structure performed by general dicing method. The edge of general device structure is smooth because all layers are cut at the same time. There is recess existing within the edge of substrate layer and the buffer layer. And this special structure can be using to determine whether a device is diced by the method according to the patent.

Although specific embodiments have been illustrated and described, it will be obvious to those skilled in the art that various modifications may be made without departing from what is intended to be limited solely by the appended claims.

What is claimed is:

1. A method for separating IC package on a substrate of a wafer level package, comprising:
forming a buffer layer on the first surface of said substrate, wherein said buffer layer has grooves denoting each one of said IC package;
etching said substrate of said wafer level package device along said grooves, thereby forming openings; and
cutting said IC package along a cutting line by mechanical force from a second surface or said first surface.

2. The method in claim 1, wherein the material of said buffer layer includes photo epoxy.

3. The method in claim 1, further comprising filling core material into said openings before performing said cutting.

4. The method in claim 3, wherein said core material comprise silicone rubber, silicone resin, elastic PU, porous PU, acrylic rubber, blue tape or UV tape.

5. The method in claim 1, wherein said etching step includes wet etching process, wherein an etching solution for said includes: ferric chloride, cupric chloride, and ammonium persulfate.

6. The method in claim 1, wherein the material of said substrate layer in said etching step comprises silicon, glass, alloy 42, quartz or ceramic.

7. The method in claim 1, wherein said mechanical force is performed by a knife.

8. A method for separating IC package on a substrate of a wafer level package, comprising:
forming a buffer layer on the first surface of said substrate, wherein said buffer layer has grooves denoting each one of said package;
cutting said package along a cutting line by mechanical force from a second surface or said first surface; and
etching through said substrate of said wafer level package device along said grooves.

9. The method in claim 8, wherein the material of said buffer layer includes photo epoxy.

10. The method in claim 8, wherein said etching step includes wet etching process, wherein an etching solution for said includes: ferric chloride, cupric chloride, and ammonium persulfate.

11. The method in claim 8, wherein the material of said substrate layer in said etching step comprises silicon, glass, alloy 42, quartz or ceramic.

12. The method in claim 8, wherein said mechanical force is performed by a knife.

13. A semiconductor device package structure, comprising:
a die having a plurality of electrical connections on a first surface of said die;
a plurality of conductive balls coupled to said connections;
a substrate adhered on a second surface of said die;
a first buffer layer formed on said substrate and adjacent to said die; and
a second buffer layer, wherein said second buffer layer is configured over said substrate, wherein said substrate and said second buffer layer have recesses to said first buffer layer.

14. The structure in claim 13, wherein said recesses in said second buffer layer are approximate the half widths of said grooves.
